(19) United States
(12) Patent Application Publication
(10) Pub. No.: US 2024/0072014 A1
(43) Pub. Date: Feb. 29, 2024

(54) MICRO-LIGHT EMITTING DIODE DISPLAY AND METHODS OF MANUFACTURING AND OPERATING THE SAME

(71) Applicant: SAMSUNG ELECTRONICS CO., LTD., Suwon-si (KR)

(72) Inventors: Kiho KONG, Suwon-si (KR); Junhee Chol, Suwon-si (KR); Eunsung Lee, Suwon-si (KR)

(73) Assignee: SAMSUNG ELECTRONICS CO., LTD., Suwon-si (KR)

(21) Appl. No.: 18/106,855

(22) Filed: Feb. 7, 2023

(30) Foreign Application Priority Data
Aug. 23, 2022 (KR) 10-2022-0105780

(51) Int. Cl. H01L 25/075; H01L 33/00; H01L 33/10; H01L 33/14; H01L 33/62

(52) U.S. Cl. CPC H01L 25/0753; H01L 33/005; H01L 33/10; H01L 33/145; H01L 33/62; H01L 2933/0066

(57) ABSTRACT

An ultra-high pixel per inch (ppi) micro-light-emitting diode (LED) display includes a micro-LED layer including a plurality of micro-LEDs, a backplane layer including a switching device connected to the micro-LED layer, and a field shielding member provided between the plurality of micro-LEDs and the switching device, the field shielding member configured to shield the switching device from a field applied to the switching device from the plurality of micro-LEDs during an operation of the micro-LED display, where the micro-LED layer and the backplane layer form a single body in a sequentially stacked structure.

### CROSS-REFERENCE TO RELATED APPLICATION

This application is based on and claims priority to Korean Patent Application No. 10-2022-0105780, filed on Aug. 23, 2022, in the Korean Intellectual Property Office, the disclosure of which is incorporated herein by reference in its entirety.

### BACKGROUND

### 1. Field

Example embodiments of the present disclosure relate to a micro-light emitting diode (micro-LED) display, and more particularly, to an ultra-high pixel per inch (ppi) micro-LED display and methods of manufacturing and operating the same.

### 2. Description of the Related Art

In a micro-light emitting diode (micro-LED) display, a backplane and a micro-LED array may be bonded by a pad-to-pad method. However, with micro-LED displays that require ultra-high pixel per inch (ppi) (e.g., mobile virtual reality (VR), augmented reality (AR), wearable devices, etc.), a backplane and a micro-LED are formed as a single body, and as the ppi increases, a thin film transistor (TFT) channel is formed on the micro-LED. Thus, various problems may appear.

### SUMMARY

Provided are an ultra-high pixel per inch (ppi) micro-light emitting diode (micro-LED) display configured to shield a bottom gate effect, a method of manufacturing the micro-LED display, and a method of operating the micro-LED display.

Additional aspects will be set forth in part in the description which follows and, in part, will be apparent from the description, or may be learned by practice of the presented embodiments.

According to an aspect of an embodiment, an ultra-high ppi micro-LED display may include a micro-LED layer including a plurality of micro-LEDs, a backplane layer including a switching device connected to the micro-LED layer, and a field shielding member provided between the plurality of micro-LEDs and the switching device, the field shielding member configured to shield the switching device from a field applied to the switching device from the plurality of micro-LEDs during an operation of the micro-LED display, where the micro-LED layer and the backplane layer form a single body in a sequentially stacked structure.

The field shielding member may include a reflective layer configured to reflect light emitted from the plurality of micro-LEDs and a metal layer provided as a contact terminal and configured to apply a voltage to the reflective layer.

The plurality of micro-LEDs may include at least one active micro-LED and an inactive dummy micro-LED.

The reflective layer may be provided on a surface of the at least one active micro-LED facing the switching device, the reflective layer may not electrically contact the at least one active micro-LED, and the metal layer may be provided on the inactive dummy micro-LED.

The micro-LED display may include a current blocking layer provided on at least a side surface of the at least one active micro-LED and between the reflective layer and the at least one active micro-LED.

The switching device may include a channel layer, the field shielding member may be connected to a first side of the channel layer, and the micro-LED may be connected to a second side of the channel layer that is different from the first side of the channel layer.

The entire channel layer may be provided on the field shielding member.

The field shielding member may include a metal layer.

The micro-LED display may further include a reflective layer contacting the plurality of micro-LEDs, where the reflective layer is between the plurality of micro-LEDs and the switching device and the reflective layer may be connected to the channel layer through the metal layer.

The switching device may include a plurality of switching devices, the field shielding member may include a single metal layer corresponding to the plurality of switching devices and separated from the plurality of micro-LEDs and a metal layer may be provided as a contact terminal and configured to apply a voltage to the single metal layer.

The switching device may include a channel layer and the micro-LED layer is connected to one side of the channel layer.

A reflective layer may be provided between the switching device and the plurality of micro-LEDs, and the plurality of micro-LEDs is connected to the channel layer through the reflective layer.

According to an aspect of the disclosure, a method of manufacturing an ultra-high ppi micro-LED display may include forming a plurality of micro-LEDs on a substrate, forming a reflective layer on the plurality of micro-LEDs, forming an interlayer insulating layer on the reflective layer, forming a switching device on the interlayer insulating layer, and connecting the switching device to the plurality of micro-LEDs, where the plurality of micro-LEDs includes a plurality of active micro-LEDs and an inactive micro-LED, the switching device is connected to the plurality of active micro-LEDs, the reflective layer does not directly contact the plurality of micro-LEDs, and a metal layer as a voltage applying terminal is formed on the reflective layer and on the inactive micro-LED.

The method may further include forming a current blocking layer between the reflective layer and the plurality of micro-LEDs.

According to an aspect of the disclosure, a method of manufacturing an ultra-high ppi micro-LED display may include forming a micro-LED on a substrate, forming a reflective layer on the micro-LED, the reflective layer contacting the micro-LED, forming an interlayer insulating layer on the reflective layer, forming a field shielding member on the interlayer insulating layer, forming a buffer layer on the field shielding member, the field shielding member being provided on the interlayer insulating layer, forming a switching device on the buffer layer, and connecting a first side of the switching device to the field shielding member and a second side of the switching device to the micro-LED.

The switching device may include a channel layer connected to the field shielding member and the micro-LED, the field shielding member may include a metal layer, and the entire channel layer may be on the metal layer.

According to an aspect of the disclosure, a method of manufacturing an ultra-high ppi micro-LED display may include forming a micro-LED on a substrate, forming a reflective layer on the micro-LED, the reflective layer contacting the micro-LED, forming an interlayer insulating layer on the reflective layer, forming a field shielding member on the interlayer insulating layer, forming a buffer layer on the field shielding member, the field shielding member being provided on the interlayer insulating layer, forming a switching device on the buffer layer, and connecting the switching device to the micro-LED, where the field shielding member includes a metal layer that does not directly contact the switching device and the micro-LED and a voltage applying terminal connected to the metal layer.

According to an aspect of the disclosure, a method of operating an ultra-high ppi micro-LED display including a micro-LED and a switching device connected to the micro-LED may include shielding the switching device from a field applied to the switching device from the micro-LED during an operation of the micro-LED display by applying, to a field shielding member, a bias voltage, where the field shielding member is between the micro-LED and the switching device and the field shielding member is electrically insulated from the micro-LED.

The switching device may include a channel layer, the field shielding member may be connected to one side of the channel layer, and the bias voltage may be supplied to the field shielding member through the switching device.

The bias voltage may be directly applied to the field shielding member without passing through the switching device.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a cross-sectional view illustrating an ultra-high pixel per inch (ppi) micro-light-emitting diode (LED) display according to an example embodiment;

FIG. 2 is a diagram illustrating an example in which a plurality of micro-LEDs form an array in the ultra-high ppi micro-LED display of FIG. 1 according to an example embodiment;

FIG. 3 is a cross-sectional view illustrating an example in which a first metal layer of FIG. 1 is formed to cover an inclined side surface and a bottom surface of a via hole instead of filling the via hole according to an example embodiment;

FIG. 4 is a cross-sectional view illustrating an ultra-high ppi micro-LED display according to an example embodiment;

FIG. 5 is a cross-sectional view illustrating an example in which an upper surface of a reflective layer in FIG. 4 is flat according to an example embodiment;

FIG. 6 is a cross-sectional view illustrating an ultra-high ppi micro-LED display according to an example embodiment;

FIG. 7 is a diagram illustrating a metal layer included in the third display of FIG. 6 and provided to block a bottom gate effect according to an example embodiment;

FIGS. 8, 9, 10, 11, 12, 13, and 14 are cross-sectional views illustrating a method of manufacturing an ultra-high ppi micro-LED display according to an example embodiment;

FIG. 15 is a plan view of FIG. 14 cut along line 15-15′ in FIG. 14;

FIG. 16 is a cross-sectional view illustrating a method of manufacturing an ultra-high ppi micro-LED display according to an example embodiment; and

FIGS. 17, 18, 19, 20, and 21 are cross-sectional views illustrating a method of manufacturing an ultra-high ppi micro-LED display according to an example embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, an ultra-high pixel per inch (ppi) micro-light emitting diode (micro-LED) display and a method of manufacturing and operating the same according to an example embodiment will be described in detail with reference to the accompanying drawings. In the drawings, thicknesses of layers and regions may be exaggerated for clarification of the specification.

The embodiments of the disclosure are capable of various modifications and may be embodied in many different forms. Also, in a layer structure described below, when an element or layer is referred to as being “on” or “above” another element or layer, the element or layer may be directly on another element or layer or intervening elements or layers. In the descriptions below, like reference numerals refer to like elements throughout.

The singular forms “a,” “an” and “the” are intended to include the plural forms as well, unless the context clearly indicates otherwise. It should be understood that, when a part “comprises” or “includes” an element in the specification, unless otherwise defined, other elements are not excluded from the part and the part may further include other elements.

The term “above” and similar directional terms may be applied to both singular and plural. With respect to operations that constitute a method, the operations may be performed in any appropriate sequence unless the sequence of operations is clearly described or unless the context clearly indicates otherwise. The operations may not necessarily be performed in the order of sequence.

Also, in the specification, the term “units” or “ . . . modules” denote units or modules that process at least one function or operation, and may be realized by hardware, software, or a combination of hardware and software.

Connections or connection members of lines between components shown in the drawings illustrate functional connections and/or physical or circuit connections, and the connections or connection members can be represented by replaceable or additional various functional connections, physical connections, or circuit connections in an actual apparatus.

All examples or example terms are simply used to explain in detail the technical scope of the disclosure, and thus, the scope of the disclosure is not limited by the examples or the example terms as long as it is not defined by the claims.

An ultra-high ppi micro-LED display according to an example embodiment is described.

The ultra-high ppi micro-LED display may refer to a display that includes micro-LEDs with high density, but the micro-LEDs are small enough to be difficult to apply a micro-LED transfer method of the related art. For example, an ultra-high ppi micro-LED display may include more than 5,000 micro-LEDs per inch.

In the illustrated micro-LED display, the micro-LED may be used as an R pixel emitting red light, a G pixel emitting green light, or a B pixel emitting blue light.

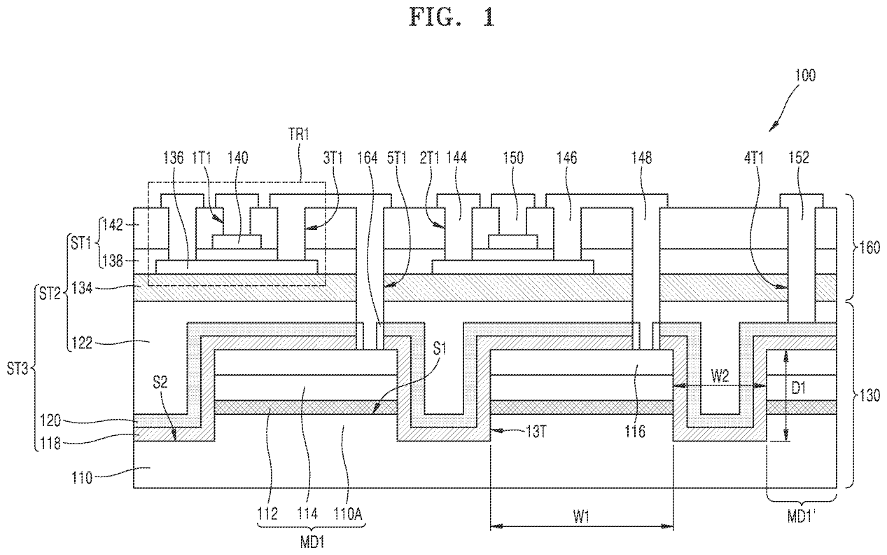

FIG. 1 is a cross-sectional view illustrating an ultra-high pixel per inch (ppi) micro-light-emitting diode (LED) display according to an example embodiment. FIG. 1 shows an ultra-high ppi micro-LED display 100 (hereinafter, referred to as a first display) according to an example embodiment.

Referring to FIG. 1, the first display 100 includes a micro-LED layer 130 and a backplane layer 160 connected to the micro-LED layer 130. The micro-LED layer 130 includes a plurality of micro-LEDs MD1. The plurality of micro-LEDs MD1 share a substrate 110 and are connected to each other through the substrate 110. Each of the plurality of micro-LEDs MD1 includes a first semiconductor layer 110A, an active layer 112, and a second semiconductor layer 114, which are sequentially stacked. The first semiconductor layers 110A of the plurality of micro-LEDs MD1 are connected to each other through the substrate 110. The first semiconductor layer 110A of each micro-LED MD1 may be a portion (e.g., a convex portion) of the substrate 110 that protrudes toward the active layer 112. As a result, the first semiconductor layer 110A may be a part of the substrate 110, and the substrate 110 and the first semiconductor layer 110A may include the same material. Because the substrate 110 is shared by the plurality of micro-LEDs MD1 and a portion of the substrate 110 is one layer of each micro-LED MD1 under the name of the first semiconductor layer 110A, the substrate 110 and the first semiconductor layer 110A may be collectively described as a first semiconductor layer. In addition, as may be seen in FIG. 1, the plurality of micro-LEDs MD1 are present on the substrate 110, and the plurality of micro-LEDs MD1 may be described as being formed on the substrate 110, or may be described as provided or disposed on the substrate 110.

The active layers 112 of the plurality of micro-LEDs MD1 are apart from each other, and the second semiconductor layers 114 are also apart from each other. A first electrode layer 116 is present on the second semiconductor layer 114 of each micro-LED MD1. The second semiconductor layer 114 is located between the active layer 112 and the first electrode layer 116. The first electrode layer 116 may cover an entire surface (e.g., an upper surface) of the second semiconductor layer 114 facing the first electrode layer 116, and directly contacts the second semiconductor layer 114.

The first semiconductor layer 110A may be or include a P-type semiconductor or an N-type semiconductor layer. For example, the first semiconductor layer 110A may be an N-type semiconductor layer, for example, an N-type compound semiconductor layer. The active layer 112 may be an emission layer or a light-emitting layer. For example, the active layer 112 may be or include a multi-quantum well (MQW) layer. The second semiconductor layer 114 may be a semiconductor layer of a type opposite to that of the first semiconductor layer 110A. The second semiconductor layer 114 may include a P-type semiconductor layer or an N-type semiconductor layer. For example, the second semiconductor layer 114 may be a P-type semiconductor layer or may include a P-type semiconductor layer. For example, the second semiconductor layer 114 may include a P-type compound semiconductor layer. For example, the first and second semiconductor layers 110A and 114 may include a Group III-V compound semiconductor layer, for example, a GaN layer. For example, the first semiconductor layer 110A may be a single layer or a multi-layer, and the second semiconductor layer 114 may also be a single layer or a multi-layer. For example, the first electrode layer 116 may be a single layer or a multi-layer. For example, the first electrode layer 116 may be a material layer transparent to incident light or may include a transparent material layer. For example, the first electrode layer 116 may be an indium tin oxide (ITO) layer or may include an ITO layer, but embodiments are not limited thereto. For example, the first electrode layer 116 may have a layer structure in which a nickel (Ni) layer, an ITO layer, and an aluminum (Al) layer are sequentially stacked, but embodiments are not limited thereto.

Because the first semiconductor layer 110A is a protruded portion of the substrate 110, there is a step between the first semiconductor layer 110A and the substrate 110 around the first semiconductor layer 110A. That is, an upper surface S1 of the first semiconductor layer 110A is higher than an upper surface S2 of the substrate 110 around the first semiconductor layer 110A. The active layer 112, the second semiconductor layer 114, and the first electrode layer 116 are sequentially stacked on the upper surface S1 of the first semiconductor layer 110A. Widths of the first semiconductor layer 110A, the active layer 112, the second semiconductor layer 114, and the first electrode layer 116 may be the same or substantially the same from each other. Each of the plurality of micro-LEDs MD1 has such a stacked structure and is horizontally apart from each other, and thus, a trench 13T exists between each of the plurality of micro-LEDs MD1. A depth D1 of the trench 13T may be equal to the sum of thicknesses of the first semiconductor layer 110A, the active layer 112, the second semiconductor layer 114, and the first electrode layer 116. A width W2 of the trench 13T may be less than the width W1 of the micro-LED MD1 (e.g., W1>W2).

One of the plurality of micro-LEDs MD1 may be used as a dummy micro-LED. The dummy micro-LED may denote an inactive micro-LED to which operation power is not supplied unlike an active micro-LED to which operation power is supplied. A layer structure of the dummy micro-LED may be the same as that of the active micro-LED.

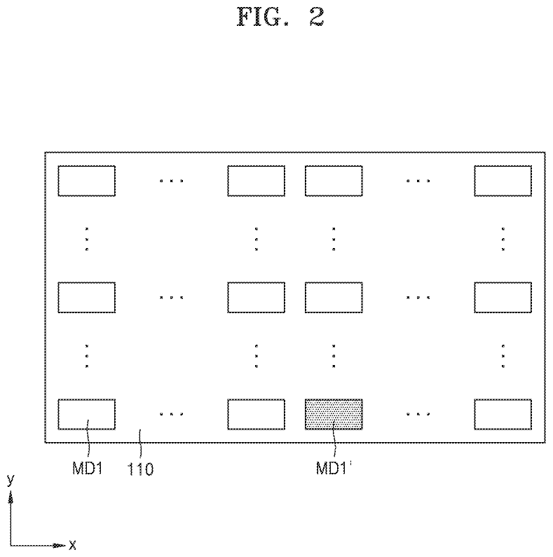

FIG. 2 is a diagram illustrating an example in which a plurality of micro-LEDs form an array in the ultra-high ppi micro-LED display of FIG. 1 according to an example embodiment. The plurality of micro-LEDs MD1 may be arranged to form an array. For example, as shown in FIG. 2, the plurality of micro-LEDs MD1 may be arranged in a first period in a first direction (e.g., an x-axis direction) and in a second period in a second direction (e.g., a y-axis direction) perpendicular to the first direction). The first and second periods may be the same or different from each other. In FIG. 2, reference numeral MD1′ denotes a dummy micro-LED.

Referring back to FIG. 1, the first electrode layer 116 and the plurality of micro-LEDs MD1 are covered with a current blocking layer 118. The current blocking layer 118 may be provided to prevent a current from directly flowing from the first semiconductor layer 110A to the second semiconductor layer 114 layer or conversely while power is supplied to each of the plurality of micro-LEDs MD1. The entire upper surface S2 of the substrate 110 may be covered with the current blocking layer 118 and may directly contact the current blocking layer 118. The upper surface S2 of the substrate 110 may include a bottom surface of the trench 13T. The current blocking layer 118 may extend on side surfaces of each micro-LED MD1 and side surfaces and an upper surface of the first electrode layer 116 on the upper surface S2 of the substrate 110. Entire both side surfaces of each micro-LED MD1 may be covered with the current blocking layer 118, and may directly contact the current blocking layer 118. The entire both side surfaces and the entire upper surface of the first electrode layer 116 may be covered with the current blocking layer 118 and may directly contact the current blocking layer 118. For example, the current blocking layer 118 may include a material layer that is transparent to incident light. For example, the current blocking layer 118 may be a transparent insulating layer or may include a transparent insulating layer. For example, the current blocking layer 118 may be a single layer or a multi-layer. For example, another member configured to block current may further be provided between the current blocking layer 118 and the substrate 110, and between each micro-LED MD1 and the first electrode layer 116. For example, the current blocking layer 118 may be provided only on both sides of each micro-LED MD1. In other words, the current blocking layer 118 may be provided to cover only both side surfaces of each micro-LED MD1. Due to the current blocking layer 118, it is possible to prevent a current from flowing from the first semiconductor layer 110A to the second semiconductor layer 114 layer along the side surfaces of the micro-LED MD1 or vice versa.

A reflective layer 120 is provided on the current blocking layer 118. The reflective layer 120 serves to reflect light emitted from the micro-LED MD1 to the backplane layer 160 in an opposite direction, for example, toward the substrate 110. The reflective layer 120 has conductivity and may be described as a reflective electrode layer in that a voltage may be applied to the reflective layer 120. The reflective layer 120 may be formed along a surface of the current blocking layer 118. For example, the reflective layer 120 may continuously extend onto an upper surface and side surfaces of the current blocking layer 118 and cover the entire upper surface and the side surfaces of the current blocking layer 118. For example, the reflective layer 120 may be a single layer or a multi-layer. For example, the reflective layer 120 may include a single metal layer having a mirror function, but may have a layer structure in which material layers that are different from each other are stacked to have a mirror function. For example, the reflective layer 120 may have a layer structure including a titanium (Ti) layer and an aluminum (Al) layer, for example, the reflective layer 120 may have a multi-layer structure such as Ti/Al/Ti. Like the current blocking layer 118, the reflective layer 120 may have a substantially uniform thickness throughout. The current blocking layer 118 and the reflective layer 120 may have the same thickness or thicknesses different from each other. For example, the current blocking layer 118 and the reflective layer 120 are directly contacting each other, but an additional transparent material layer may be provided therebetween.

In view of the trench 13T, the current blocking layer 118 and the reflective layer 120 are sequentially stacked on the sides and bottom of the trench 13T. Although the thicknesses of the current blocking layer 118 and the reflective layer 120 are not sufficient to fill the trench 13T, the trench 13T may be completely filled with the sequentially stacked current blocking layer 118 and reflective layer 120.

The reflective layer 120 is covered with a first interlayer insulating layer 122. The first interlayer insulating layer 122 may cover an entire upper surface and side surfaces of the reflective layer 120, and may completely fill the trench 13T in which the current blocking layer 118 and the reflective layer 120 are stacked. The first interlayer insulating layer 122 may be a planarization layer for forming the backplane layer 160, and an upper surface thereof may be substantially flat. For example, the first interlayer insulating layer 122 may be a silicon oxide layer or may include a silicon oxide layer, but embodiments are not limited thereto. For example, the first interlayer insulating layer 122 may have a single-layer or multi-layer structure. The backplane layer 160 is provided on the first interlayer insulating layer 122.

Specifically, a buffer layer 134 is formed on the first interlayer insulating layer 122. The buffer layer 134 may cover an entire upper surface of the first interlayer insulating layer 122 and may directly contact the first interlayer insulating layer 122. The buffer layer 134 may have a uniform thickness as a whole. For example, the buffer layer 134 may have a single-layer or multi-layer structure. For example, the buffer layer 134 may be a silicon oxide (e.g., SiO₂) layer or may include a silicon oxide layer, but embodiments are not limited thereto. A plurality of channel layers 136 separated from each other are formed on the buffer layer 134. The channel layer 136 may be described as an active layer. The plurality of channel layers 136 may be provided in the same number as the plurality of micro-LEDs MD1. The plurality of channel layers 136 may be disposed to correspond to the plurality of micro-LEDs MD1 one-to-one. Considering that dummy micro-LEDs MD1′ are also included in the plurality of micro-LEDs MD1, the plurality of channel layers 136 may be provided in the same number as the number of active micro-LEDs of the plurality of micro-LEDs MD1. Accordingly, the plurality of channel layers 136 may correspond one-to-one with the active micro-LED. Each of the channel layers 136 may be provided on the corresponding micro-LED MD1, but may be provided slightly biased toward one side for connection between a TFT of the backplane layer 160 and the micro-LED MD1. For example, the channel layer 136 may be or include a material layer having conductivity. For example, the channel layer 136 may include a single layer or a layer structure in which a single layer is stacked in multiple layers. For example, the channel layer 136 may include a doped monocrystalline or polycrystalline silicon layer, but embodiments are not limited thereto.

A second interlayer insulating layer 138 covering the plurality of channel layers 136 is formed on the buffer layer 134. The second interlayer insulating layer 138 may cover side surfaces and upper surfaces of the channel layer 136. For example, the second interlayer insulating layer 138 may be or include a silicon oxide (e.g., SiO₂) layer, but embodiments are not limited thereto. An entire upper surface of the second interlayer insulating layer 138 may be flat or substantially flat. A plurality of gate electrode layers 140 apart from each other are provided on the second interlayer insulating layer 138. The plurality of gate electrode layers 140 may be provided in the same number as the number of the plurality of channel layers 136, but the gate electrode layers may not be provided on a region of the second interlayer insulating layer 138 in which the dummy micro-LED MD1′ is provided. The plurality of gate electrode layers 140 and the plurality of channel layers 136 may have a one-to-one correspondence. Accordingly, one gate electrode layer 140 is present on one channel layer 136 with the second interlayer insulating layer 138 therebetween. The gate electrode layer 140 may be located in the middle region of the channel layer 136, but embodiments are not limited thereto. A portion of the second interlayer insulating layer 138 formed between the gate electrode layer 140 and the channel layer 136 serves as a gate insulating layer while preventing the gate electrode layer 140 from contacting with the channel layer 136. For example, the gate electrode layer 140 may include a single layer or a plurality of layers. For example, the gate electrode layer 140 may be a metal layer or may include a metal layer. For example, the gate electrode layer 140 may be a molybdenum (Mo) layer or may include a molybdenum layer, but embodiments are not limited thereto. A third interlayer insulating layer 142 covering the gate electrode layer 140 is provided on the second interlayer insulating layer 138. An upper surface of the third interlayer insulating layer 142 may be entirely flat. For example, the third interlayer insulating layer 142 may include a dielectric layer similar to the first and second interlayer insulating layers 122 and 138. For example, the third interlayer insulating layer 142 may include a silicon oxide (e.g., SiO₂) layer, but embodiments are not limited thereto.

A plurality of first via holes 1T1 are formed in the third interlayer insulating layer 142. In other words, the third interlayer insulating layer 142 includes a plurality of first via holes 1T1. The first via hole 1T1 may be referred to as a “first through hole” or a “first contact hole”. The number of the plurality of first via holes 1T1 may be the same as the number of the plurality of gate electrode layers 140. The plurality of first via holes 1T1 may be for exposing the plurality of gate electrode layers 140. Accordingly, the plurality of first via holes 1T1 and the plurality of gate electrode layers 140 may correspond one-to-one. The first via hole 1T1 is not formed in a region of the third interlayer insulating layer 142 corresponding to the dummy micro-LED MD1′. A width of the first via hole 1T1 may be less than a width of the gate electrode layer 140. The plurality of first via holes 1T1 are filled with a first metal layer 150. The first metal layer 150 may completely fill the first via hole 1T1 and may extend over a partial region of the third interlayer insulating layer 142 around the first via hole 1T1.

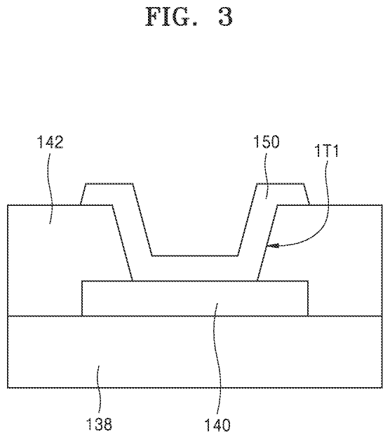

FIG. 3 is a cross-sectional view illustrating an example in which a first metal layer of FIG. 1 is formed to cover an inclined side surface and a bottom surface of a via hole instead of filling the via hole according to an example embodiment. The first via hole 1T1 may be completely filled with the first metal layer 150, but as shown in FIG. 3, the first via hole 1T1 may have a structure in which an inner surface of the first via hole 1T1 is inclined, and thus, a width of the first via hole 1T1 narrows towards downward. The first metal layer 150 covers the inclined surface of the first via hole 1T1 and an upper surface of the gate electrode layer 140 exposed through the first via hole 1T1, but does not completely fill the first via hole 1T1. The shape of a via hole shown in FIG. 3 and the structure of the first metal layer 150 may be applied to other via holes and metal layers to be described later.

The first metal layer 150 may be described as a first wiring, a first wiring layer, a first contact wiring layer, a first contact layer, or the like. For example, the first metal layer 150 may have a single layer or a multi-layer structure. For example, the first metal layer 150 may be or include a titanium layer. For example, the first metal layer 150 may include a layer structure including titanium and aluminum. For example, the metal layer 150 may include a layer structure including a sequentially stacked titanium layer/aluminum layer/titanium layer (Ti/Al/Ti).

A plurality of second via holes 2T1 and a plurality of third via holes 3T1 that pass through the second and third interlayer insulating layers 138 and 142 are formed in a first stack ST1 including the second and third interlayer insulating layers 138 and 142. That is, the first stack ST1 includes a plurality of second via holes 2T1 and a plurality of third via holes 3T1 apart from plurality of second via holes 2T1. The number of the plurality of second via holes 2T1 and the number of the plurality of third via holes 3T1 may be the same. The number of the plurality of second via holes 2T1 may be the same as the number of the channel layers 136. The second via hole 2T1 is on the left side of the gate electrode layer 140, and the third via hole 3T1 is on the right side of the gate electrode layer 140, respectively. The second and third via holes 2T1 and 3T1 face each other with the gate electrode layer 140 therebetween and are apart from the gate electrode layer 140. The second via hole 2T1 is located between the gate electrode layer 140 and the left end of the channel layer 136 and the channel layer 136 is exposed through the second via hole 2T1. The third via hole 3T1 is located between the gate electrode layer 140 and the right end of the channel layer 136, and the channel layer 136 is exposed through the third via hole 3T1. The second via hole 2T1 is filled with a second metal layer 144, and the channel layer 136 exposed through the second via hole 2T1 is covered with the second metal layer 144. The second metal layer 144 may completely fill the second via hole 2T1 and extend over a partial region of the third interlayer insulating layer 142 around the second via hole 2T1. However, the second metal layer 144 does not contact the first metal layer 150. The second metal layer 144 may be a source electrode or a source electrode layer connected to one side of the channel layer 136. For example, the material, layer configuration, or layer structure of the second metal layer 144 may be the same as that of the first metal layer 150, but may be different from each other.

The third via hole 3T1 is filled with a third metal layer 146, and the channel layer 136 exposed through the third via hole 3T1 is covered with the third metal layer 146. The third metal layer 146 may completely fill the third via hole 3T1 and may extend over a partial region of the third interlayer insulating layer 142 around the third via hole 3T1. However, the third metal layer 146 is apart from the first metal layer 150, and does not contact the first metal layer 150. The third metal layer 146 may be a drain electrode or a drain electrode layer connected to the other side of the channel layer 136. For example, the material, layer configuration, or layer structure of the third metal layer 146 may be the same as that of the first metal layer 150 or the second metal layer 144, but may be different from each other.

A second stack ST2 including the first interlayer insulating layer 122, the buffer layer 134, the second interlayer insulating layer 138, and the third interlayer insulating layer 142 sequentially stacked is present on the reflective layer 120 on the dummy micro-LED MD1′. A fourth via hole 4T1 is formed in the second stack ST2. That is, the second stack ST2 includes the fourth via hole 4T1. The reflective layer 120 is exposed through the fourth via hole 4T1. The fourth via hole 4T1 is present above the dummy micro-LED MD1′. Accordingly, the number of the fourth via holes 4T1 may be the same as the number of the dummy micro-LEDs MD1′. The fourth via hole 4T1 is filled with a fourth metal layer 152. For example, the fourth metal layer 152 may completely fill the fourth via hole 4T1 and extend onto a partial region of the third interlayer insulating layer 142 around the fourth via hole 4T1. The fourth metal layer 152 is apart from the first to third metal layers 150, 144, and 146, and is also apart from the fifth metal layer 148 to be described later. For example, the fourth metal layer 152 may be formed in the fourth via hole 4T1 in the same shape as the first metal layer 150 of FIG. 3 is formed in the first via hole 1T1. The fourth metal layer 152 covers an entire surface of the reflective layer 120 exposed through the fourth via hole 4T1 and directly contacts the exposed reflective layer 120. The fourth metal layer 152 may be a terminal for applying a bias voltage to the reflective layer 120 to block a bottom gate effect. That is, as a voltage is applied to the first electrode layer 116 through a fifth metal layer 148, which is described later, the first electrode layer 116 may serve as a bottom gate with respect to the channel layer 136. Accordingly, when a voltage is applied to the first electrode layer 116, a bottom gate effect may appear in the channel layer 136. Due to the bottom gate effect, a normal operation of a switching device TR1 may be inhibited. That is, a threshold voltage and/or a current-voltage characteristic of the switching device TR1 formed on the buffer layer 134 is (are) changed. However, a bias voltage capable of minimizing or blocking a bottom gate effect may be applied to the reflective layer 120 through the fourth metal layer 152, and due to the application of the bias voltage to the reflective layer 120, a field applied to the channel layer 136 of the switching device TR1 may be shielded by the bottom gate effect.

The reflective layer 120 may be described as a bottom gate effect blocking layer. In addition, because the reflective layer 120 serves to block or shield a bottom gate effect as well as to reflect light, it may be described as a multifunctional layer. The switching device TR1 may be a field effect transistor used to drive the micro-LED MD1, and may be, for example, a thin film transistor, but embodiments are not limited thereto. For example, the material and layer configuration or layer structure of the fourth metal layer 152 may be the same as or different from those of the first metal layer 150 the second metal layer 144, or the third metal layer 146.

A third stack ST3 is present on the plurality of micro-LEDs MD1. That is, the third stack ST3 including the current blocking layer 118, the reflective layer 120, the first interlayer insulating layer 122, the buffer layer 134, the second interlayer insulating layer 138, and the third interlayer the insulating layer 142 sequentially stacked is present on the first electrode layer 116. A plurality of fifth via holes 5T1 penetrating through the entire third stack ST3 are formed in the third stack ST3. That is, the third stack ST3 includes a plurality of fifth via holes 5T1 separated from each other. The plurality of fifth via holes 5T1 are apart from the first to fourth via holes 1T1 to 4T1. The number of the plurality of fifth via holes 5T1 may be the same as the number of active micro-LEDs MD1. The plurality of fifth via holes 5T1 may correspond to the plurality of active micro-LEDs MD1 one-to-one. The first electrode layer 116 is exposed through the fifth via hole 5T1.

For example, the size of the fifth via hole 5T1 may be as small as possible in order to minimize a decrease in the light reflection efficiency of the reflective layer 120 due to the formation of the fifth via hole 5T1.

As shown in FIG. 1, the fifth via hole 5T1 may be located near the right end of the first electrode layer 116 and is apart from the right end. By disposing the fifth via hole 5T1 in this way, the switching device TR1 may be disposed on the micro-LED MD1 or may be substantially disposed on the micro-LED MD1. A fifth metal layer 148 is formed in the fifth via hole 5T1, and the fifth metal layer 148 may extend onto the third interlayer insulating layer 142 to be connected to the third metal layer 146. For example, the fifth metal layer 148 and the third metal layer 146 may include the same material. For example, the fifth metal layer 148 may completely fill the fifth via hole 5T1, but the fifth metal layer 148 may be formed in the fifth via hole 5T1 in the same shape as the first metal layer 150 of FIG. 3 is formed in the first via hole 1T1. The fifth metal layer 148 covers the entire upper surface of the first electrode layer 116 exposed through the fifth via hole 5T1 and directly contacts the exposed first electrode layer 116. Accordingly, a voltage may be applied to the micro-LED MD1 through the fifth metal layer 148 connected to the third metal layer 146 and the substrate 110. The material, layer configuration, or layer structure of the fifth metal layer 148 may be the same as one of the first to fourth metal layers 150, 144, 146, and 152, but may be different. For example, the fifth metal layer 148 may include a material layer having a relatively high reflective efficiency with respect to light emitted from the micro-LED MD1. In this way, a decrease in the reflection efficiency of the reflective layer 120 due to the formation of the fifth via hole 5T1 may be minimized.

For example, an insulating layer 164 may be provided between the fifth metal layer 148 and at least the reflective layer 120 in the fifth via hole 5T1. The insulating layer 164 may be provided to prevent the fifth metal layer 148 from contacting the reflective layer 120.

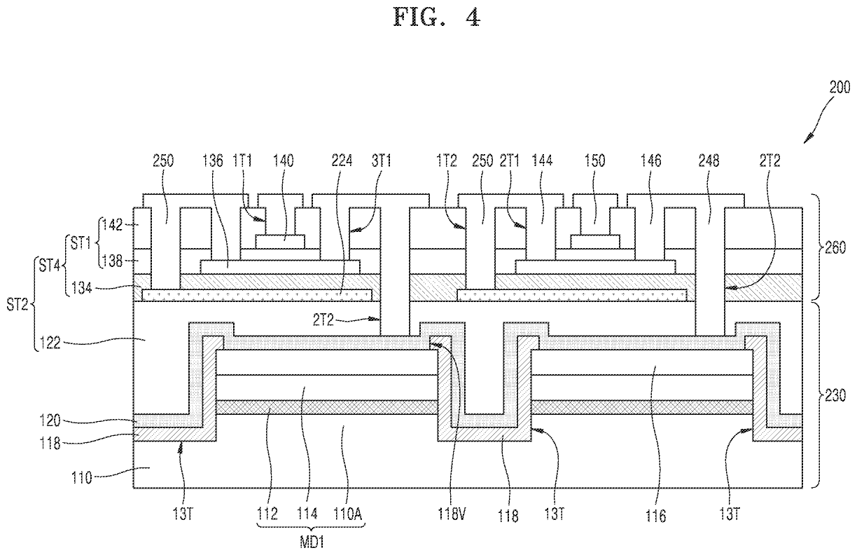

FIG. 4 is a cross-sectional view illustrating an ultra-high ppi micro-LED display according to an example embodiment. FIG. 4 shows a micro-LED display 200 (hereinafter, a second display) according to an example embodiment. Only parts different from the first display 100 described above are described, and like reference numerals denote like members.

Referring to FIG. 4, the second display 200 includes a second micro-LED layer 230 and a second backplane layer 260 connected to the second micro-LED layer 230. Unlike the first micro-LED layer 130, the second micro-LED layer 230 does not include a dummy micro-LED MD1′. In the second micro-LED layer 230, the current blocking layer 118 extends on a partial region of the upper surface of the first electrode layer 116, and the current blocking layer 118 includes a via hole 118V through which the upper surface of the first electrode layer 116 is exposed. The via hole 118V may be described as a through hole. The current blocking layer 118 covers only the upper surface, adjacent to both ends, of the first electrode layer 116, and most of the upper surface of the first electrode layer 116 is exposed through the via hole 118V. The via hole 118V is filled with the reflective layer 120, and the reflective layer 120 may directly contact the entire upper surface of the first electrode layer 116 exposed through the via hole 118V. The reflective layer 120 disposed in this way directly contacts an eighth metal layer 248 connected to the third metal layer 146. Accordingly, in the second display 200, the reflective layer 120 may serve as an electrode layer for supplying power to the micro-LED MD1 as well as a light reflection function.

In the second display 200, a plurality of sixth metal layers 224 apart from each other are disposed between the first interlayer insulating layer 122 and the buffer layer 134. The plurality of sixth metal layers 224 are disposed to be apart from each other on a flat upper surface of the first interlayer insulating layer 122, and are covered with the buffer layer 134. The number of the plurality of sixth metal layers 224 may be the same as the number of the channel layers 136 or the number of the micro-LEDs MD1. The sixth metal layer 224 is located between the channel layer 136 and the micro-LED MD1. Accordingly, the second display 200 may include the plurality of sixth metal layers 224, and the plurality of sixth metal layers 224 may correspond one-to-one with the channel layer 136 and may also correspond one-to-one with the micro-LED MD1. Most of the sixth metal layer 224 is located on the micro-LED MD1, and the entire channel layer 136 is located on the sixth metal layer 224. In other words, a width of the channel layer 136 is less than a width of the sixth metal layer 224, and both ends of the channel layer 136 do not deviate from both ends of the sixth metal layer 224. As a result, when viewed from below the sixth metal layer 224, the channel layer 136 is completely covered by the sixth metal layer 224. When a voltage is applied to the first electrode layer 116 through the eighth metal layer 248 and the reflective layer 120 for driving the micro-LED (MD1), because a voltage having a polarity opposite to the voltage applied to the first electrode layer 116 is applied to the sixth metal layer 224 through a seventh metal layer 250 connected to the second metal layer 144, a field generated in a driving process of the micro-LED MD1 may be blocked by the sixth metal layer 224. In this regard, the sixth metal layer 224 may be a member (e.g., a back gate) that blocks a bottom gate effect like the reflective layer 120 in the first display 100. For example, the material and layer configuration or layer structure of the sixth metal layer 224 may be the same as that of the gate electrode layer 140, but may be different from each other.

A plurality of sixth via holes 1T2 is formed in a fourth stack ST4 including the buffer layer 134, the second interlayer insulating layer 138, and the third interlayer insulating layer 142 sequentially stacked in the second display 200. That is, the fourth stack ST4 includes a plurality of sixth via holes 1T2. The number of the plurality of sixth via holes 1T2 may be the same as the number of the sixth metal layers 224, the number of the channel layers 136, or the number of the micro-LEDs MD1. The sixth via hole 1T2 is located on the sixth metal layer 224 and is apart from the channel layer 136. For example, the sixth via hole 1T2 may be located between the left end of the channel layer 136 and the left end of the sixth metal layer 224. The sixth metal layer 224 is exposed through the sixth via hole 1T2. The sixth via hole 1T2 is filled with the seventh metal layer 250 which extends onto the third interlayer insulating layer 142 and is directly connected to the second metal layer 144. The seventh metal layer 250 and the second metal layer 144 may include the same material. The seventh metal layer 250 and the second metal layer 144 may be directly connected to each other to form a single body, and thus, polarities of voltages applied to the sixth metal layer 224 and the second metal layer 144 may be the same. The seventh metal layer 250 may be formed in the same shape as the first metal layer 150 formed in the first via hole 1T1 of FIG. 3. For example, the material, layer configuration, or layer structure of the seventh metal layer 250 may be the same as that of the first metal layer 150, but may be different from each other.

In the second display 200, a plurality of seventh via holes 2T2 are formed in the second stack ST2. That is, the second stack ST2 includes a plurality of seventh via holes 2T2. The plurality of seventh via holes 2T2 are respectively located between the sixth metal layers 224. The number of the plurality of seventh via holes 2T2 may be the same as the number of the switching devices TR1 or the number of the micro-LEDs MD1.

The seventh via hole 2T2 is located on the reflective layer 120 on the micro-LED MD1 and is apart from the channel layer 136 and the sixth metal layer 224. The reflective layer 120 is exposed through the seventh via hole 2T2. The seventh via hole 2T2 is filled with the eighth metal layer 248 which extends onto the third interlayer insulating layer 142 and is directly connected to the third metal layer 146. The eighth metal layer 248 and the third metal layer 146 may include the same material. The eighth metal layer 248 and the third metal layer 146 are directly connected to each other to form a single body, and accordingly, polarities of voltages applied to the reflective layer 120, the first electrode layer 116, and the third metal layer 146 may be the same. Accordingly, the polarity of the voltage applied to the sixth metal layer 224 and the polarity of the voltage applied to the reflective layer 120 may be opposite to each other. For example, like the seventh metal layer 250, the eighth metal layer 248 may be formed in the same shape as the first metal layer 150 of FIG. 3 formed in the first via hole 1T1. For example, the material, layer configuration, or layer structure of the eighth metal layer 248 may be the same as that of the first metal layer 150, but may be different from each other.

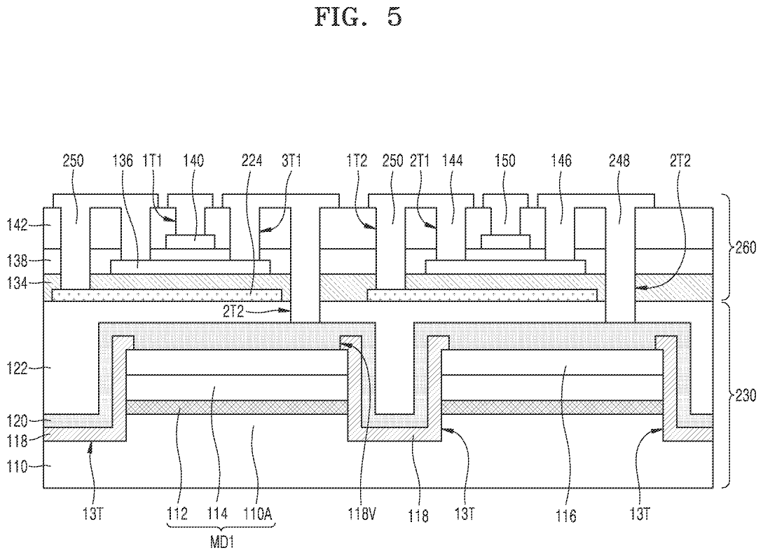

FIG. 5 is a cross-sectional view illustrating an example in which an upper surface of a reflective layer in FIG. 4 is flat according to an example embodiment. For example, the upper surface of the reflective layer 120 on the micro-LED MD1 in the second display 200 may be flat as shown in FIG. 5.

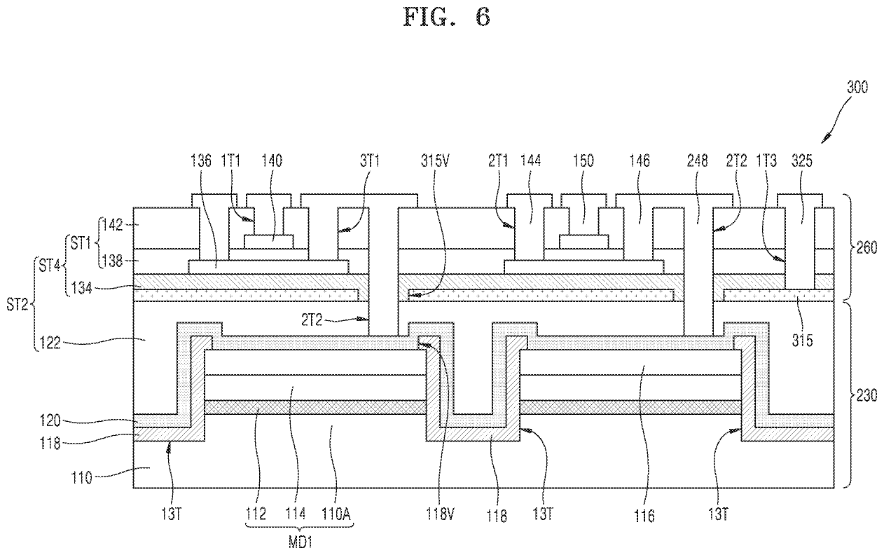

FIG. 6 is a cross-sectional view illustrating an ultra-high ppi micro-LED display according to an example embodiment. FIG. 6 shows a micro-LED display 300 (hereinafter, a third display) according to an example embodiment. Only parts different from those of the second display 200 described with reference to FIG. 4 are described, and like reference numerals denote like members.

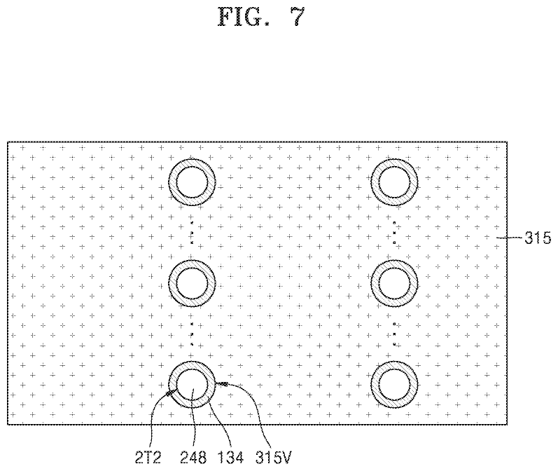

FIG. 7 is a diagram illustrating a metal layer included in the third display of FIG. 6 and provided to block a bottom gate effect according to an example embodiment. Referring to FIGS. 4, 6 and 7 together, a backplane layer 360 of the third display 300 does not include the sixth via hole 1T2 and the seventh metal layer 250 of the second display 200. In the third display 300, a ninth metal layer 315 is present on the first interlayer insulating layer 122. The ninth metal layer 315 may cover the entire upper surface of the first interlayer insulating layer 122 except for a region where the seventh via hole 2T2 is formed. The ninth metal layer 315 includes a plurality of via holes 315V apart from each other. The seventh via hole 2T2 passes through the via hole 315V, and the seventh via hole 2T2 and the via hole 315V are apart from each other and are not connected to each other. The buffer layer 134 is provided on the ninth metal layer 315, and the buffer layer 134 may completely cover the ninth metal layer 315. The buffer layer 134 is filled between the seventh via hole 2T2 and the via hole 315V. That is, the buffer layer 134 completely fills between the ninth metal layer 315 and the eighth metal layer 248. A plan view of the ninth metal layer 315 illustrated in FIG. 7 shows this relationship. The ninth metal layer 315 is present between the channel layer 136 and the micro-LED MD1, and when viewed from below the ninth metal layer 315, the channel layer 136 is completely covered by the ninth metal layer 315. For example, the ninth metal layer 315 is provided to block a bottom gate effect and may function substantially the same as the sixth metal layer 224 of the second display 200. The material, layer configuration, or layer structure of the ninth metal layer 315 may be the same as that of the sixth metal layer 224, but may be different from each other.

In the third display 300, one eighth via hole 1T3 is formed in the fourth stack ST4, but the number of the eighth via hole 1T3 may not be limited to one. The eighth via hole 1T3 is not located on the micro-LED MD1 and is vertically and horizontally apart from the micro-LED MD1. When a dummy micro-LED is included in the third display 300, the eighth via hole 1T3 may be located on the dummy micro-LED. The ninth metal layer 315 is exposed through the eighth via hole 1T3. The eighth via hole 1T3 is filled with a tenth metal layer 325. The tenth metal layer 325 may extend onto the third interlayer insulating layer 142 after completely filling the eighth via hole 1T3, but may not contact the first to third metal layers 150, 144, and 146 and the eighth metal layer 248. The tenth metal layer 325 may be provided in a form in which the first metal layer 150 of FIG. 3 is provided in the first via hole 1T1. In an operation of the third display 300, a bias voltage may be applied to the tenth metal layer 325 to block a bottom gate effect caused by driving of the micro-LED MD1. The material, layer configuration, or layer structure of the tenth metal layer 325 may be the same as that of the first metal layer 150, but may be different from each other.

On the third interlayer insulating layer 142, upper surfaces of the first to third metal layers 150, 144, and 146, the eighth metal layer 248, and the tenth metal layer 325 may form the same plane. That is, heights of the upper surfaces of the first, second, third, eighth, and tenth metal layers 150, 144, 146, 248, and 325 may be equal to each other.

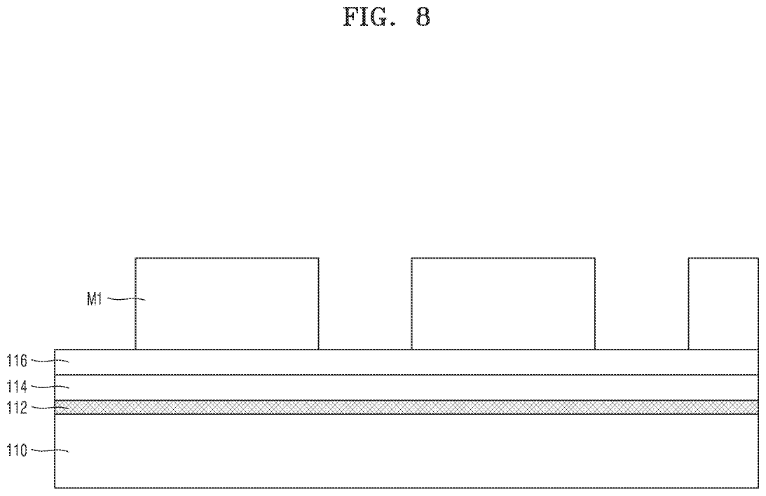

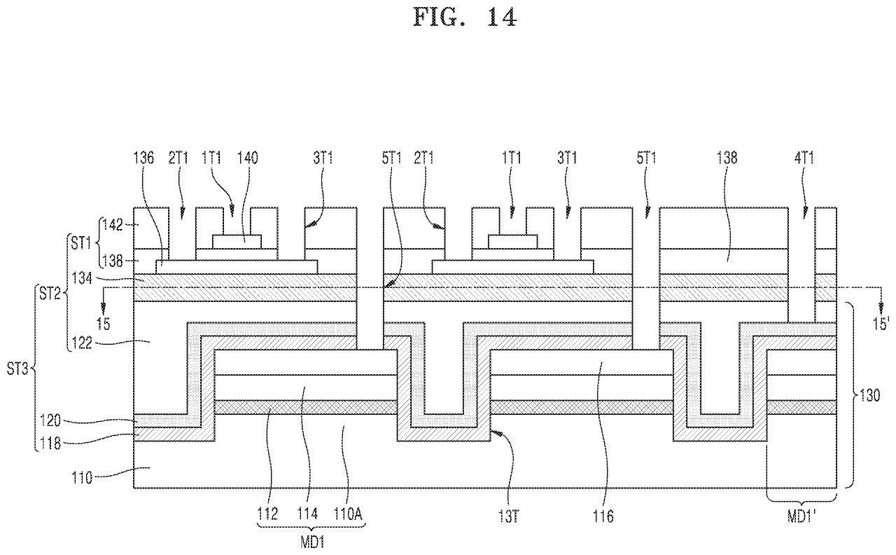

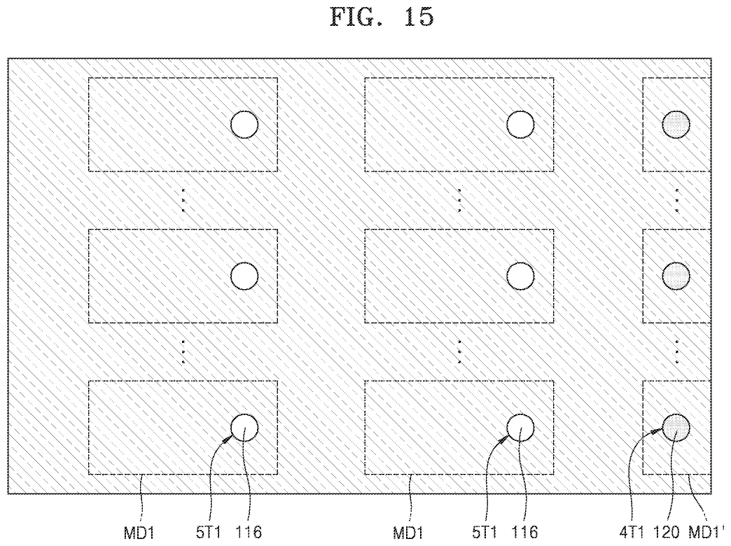

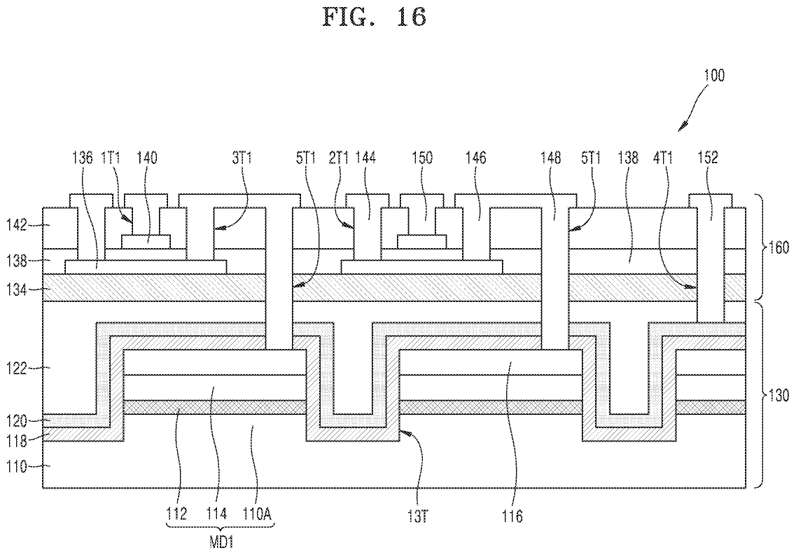

FIGS. 8, 9, 10, 11, 12, 13, and 14 are cross-sectional views illustrating a method of manufacturing an ultra-high ppi micro-LED display according to an example embodiment. FIG. 15 is a plan view of FIG. 14 cut along line 15-15′ in FIG. 14. FIG. 16 is a cross-sectional view illustrating a method of manufacturing an ultra-high ppi micro-LED display according to an example embodiment.

A method of manufacturing a micro-LED display according to an example embodiment (hereinafter, a first manufacturing method) is described in detail with reference to FIGS. 8 to 16. The first manufacturing method may be one of manufacturing methods for the first display 100. Like reference numerals as the aforementioned reference numerals indicate like members, and the descriptions thereof are omitted.

Referring to FIG. 8, an active layer 112, a second semiconductor layer 114, and a first electrode layer 116 are sequentially stacked on a substrate (a first semiconductor layer) 110. For the stacking, a chemical vapor deposition (CVD) method, a physical vapor deposition (PVD) method, a sputtering method, an atomic layer deposition (ALD) method, a growth method, etc., may be used, but the stacking method is not limited thereto. A plurality of mask patterns M1 apart from each other are formed on the first electrode layer 116. For example, the mask pattern M1 may include a photoresist pattern. The mask pattern M1 may define a region in which a micro-LED is to be formed.

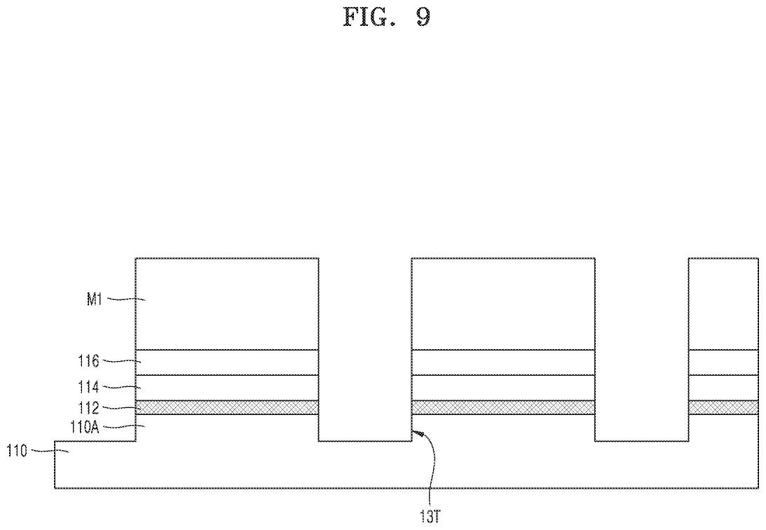

After the mask pattern M1 is formed, as shown in FIG. 9, the first electrode layer 116, the second semiconductor layer 114, the active layer 112, and the substrate 110 around the mask pattern M1 are sequentially etched using the mask pattern M1 as an etching mask. The etching, after the first electrode layer 116, the second semiconductor layer 114, and the active layer 112 around the mask pattern M1 are sequentially removed, may be performed until a trench 13T of a given depth is formed in the substrate 110. As a result of the etching, a protruding portion that is used as the first semiconductor layer 110A is formed on the substrate 110. The first semiconductor layer 110A is present between the trenches 13T.

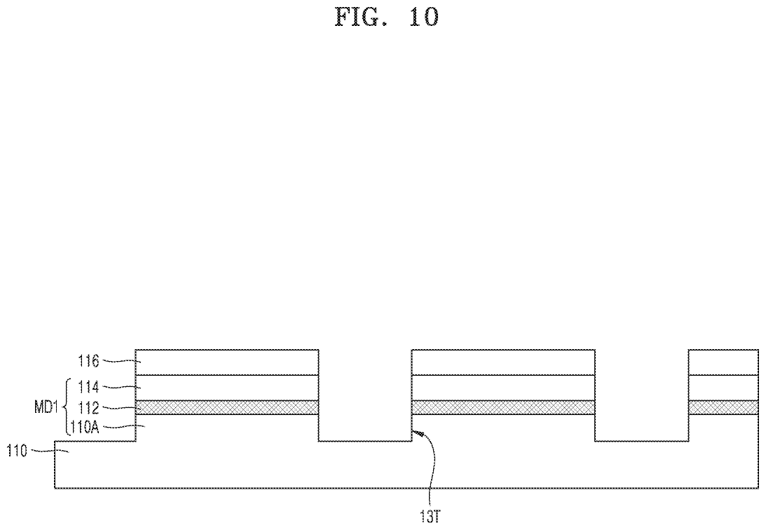

Thereafter, the mask pattern M1 is removed. In an example, the mask pattern M1 may be removed by using an ashing process. FIG. 10 shows a resultant product from which the mask pattern M1 is removed. The first semiconductor layer 110A, the active layer 112, and the second semiconductor layer 114 may form a micro-LED MD1.

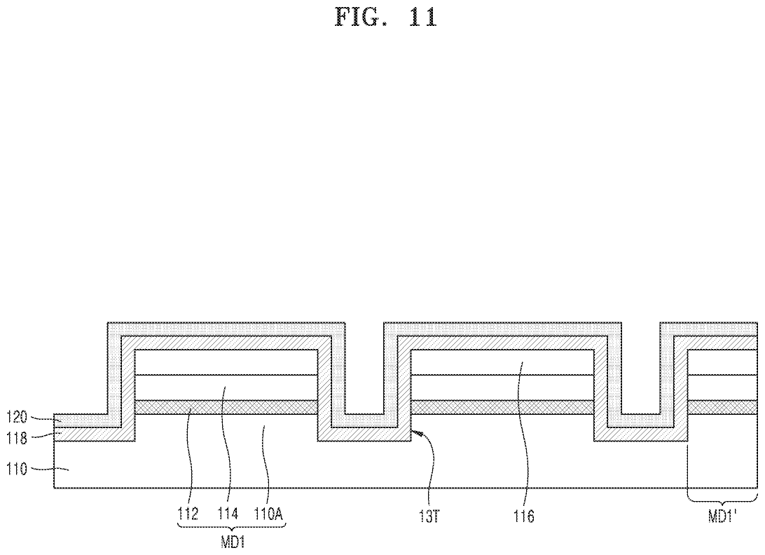

Referring to FIG. 11, a current blocking layer 118 and a reflective layer 120 covering the micro-LED MD1 are sequentially stacked on the substrate 110. The current blocking layer 118 and the reflective layer 120 may be formed along a surface of the trench 13T, and may be formed to a thickness that does not completely fill the trench 13T, but may be formed to a thickness that completely fills the trench 13T. The current blocking layer 118 may be formed to completely cover side surfaces of the micro-LED MD1 and to completely cover side surfaces and an upper surface of the first electrode layer 116.

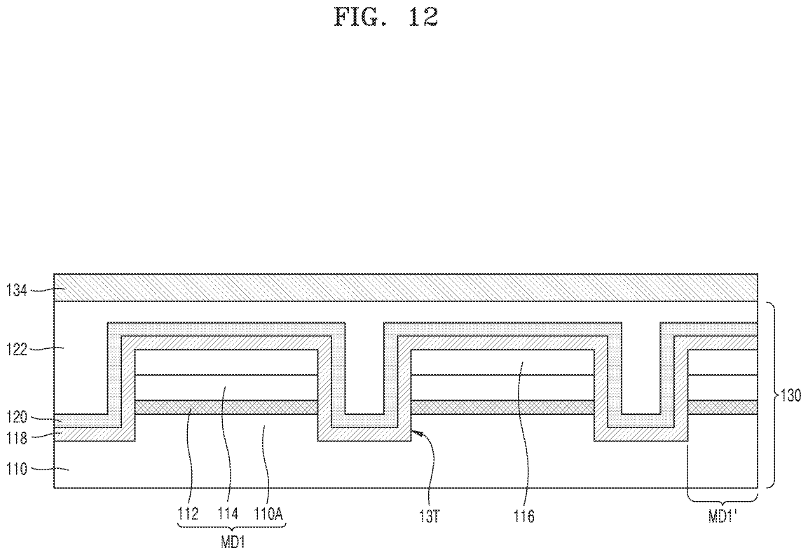

Referring to FIG. 12, a first interlayer insulating layer 122 is formed on the reflective layer 120. The first interlayer insulating layer 122 may cover an entire upper surface of the reflective layer 120 having different heights (i.e., the upper surface formed on the micro-LED MD1 and the upper surface formed on the bottom of the trench 13T), and may be formed to cover entire side surfaces connecting the upper surfaces of the reflective layer 120. In other words, the first interlayer insulating layer 122 that completely fills the trench 13T may be formed on the reflective layer 120. After the first interlayer insulating layer 122 is formed, an upper surface of the first interlayer insulating layer 122 is planarized (flatten). A buffer layer 134 is formed on the flat upper surface of the first interlayer insulating layer 122. A stack or layer structure 130 under the buffer layer 134 includes a plurality of micro-LEDs MD1, and may be referred to as a micro-LED layer 130. The micro-LED layer 130 may include an inactive dummy micro-LED MD1′ together with an active micro-LED MD1.

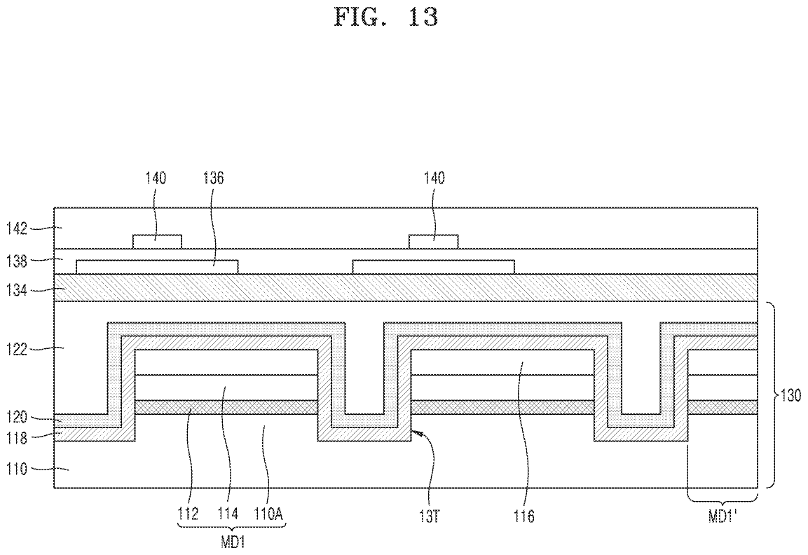

Referring to FIG. 13, a plurality of channel layers 136 apart from each other are formed on the buffer layer 134. The plurality of channel layers 136 may be formed such that, after forming a channel material layer on the buffer layer 134, the channel material layer is patterned by using a photolithography process. In an example, when the channel material layer is an amorphous silicon layer, after changing the amorphous silicon layer into a single crystal or polycrystalline silicon layer by performing a crystallization process, the photolithography process may be performed. The arrangement relationship between the plurality of channel layers 136 and the plurality of micro-LEDs MD1 is the same as the arrangement relationship described with reference to the first display 100 of FIG. 1. A second interlayer insulating layer 138 covering the plurality of channel layers 136 is formed on the buffer layer 134, and an upper surface of the second interlayer insulating layer 138 is flattened by a planarization process. The planarization process may be performed using, for example, a chemical mechanical polishing (CMP) method, but embodiments are not limited thereto. A plurality of gate electrode layers 140 are formed on the flat upper surface of the second interlayer insulating layer 138. Each gate electrode layer 140 may be formed to be located above the channel layer 136. A third interlayer insulating layer 142 covering the plurality of gate electrode layers 140 is formed on the second interlayer insulating layer 138, and an upper surface thereof is flattened by using a planarization process.

Referring to FIG. 14, a first via hole 1T1 through which the gate electrode layer 140 is exposed is formed in the third interlayer insulating layer 142, and a second via hole 2T1 exposing one side of the channel layer 136 and a third via hole 3T1 exposing the other side of the channel layer 136 are formed in the first stack ST1 including the second and third interlayer insulating layers 138 and 142. The sides of the channel layer 136 face each other with the gate electrode layer 140 therebetween, and are apart from the gate electrode layer 140. Next, a fourth via hole 4T1 is formed in the second stack ST2 including the first interlayer insulating layer 122, the buffer layer 134, and the second and third interlayer insulating layers 138 and 142. The fourth via hole 4T1 is formed on the dummy micro-LED MD1′, and the reflective layer 120 is exposed through the fourth via hole 4T1. Next, a plurality of fifth via holes 5T1 are formed in the third stack ST3 including the current blocking layer 118, the reflective layer 120, the first interlayer insulating layer 122, the buffer layer 134, the second interlayer insulating layer 138, and the third interlayer insulating layer 142 sequentially stacked on the micro-LED (MD1). The fifth via hole 5T1 is not formed on the dummy micro-LED MD1′. The first electrode layer 116 is exposed through the fifth via hole 5T1. The first electrode layer 116 contacts the second semiconductor layer 114 that is a P-type semiconductor layer of the micro-LED MD1, and thus, may be referred to as a P-side electrode layer. Accordingly, the fifth via hole 5T1 may be a via hole exposing the P-side electrode of the micro-LED MD1.

For example, the first to fifth via holes 1T1 to 5T1 may not be formed simultaneously or may be formed simultaneously, or only some of them may be formed simultaneously. For example, the first to fifth via holes 1T1 to 5T1 may be formed separately, respectively, the first to third via holes 1T1 to 3T1 having no significant difference in depth are simultaneously formed, and the fourth and fifth via holes 4T1 and 5T1 that are relatively deeper than the third via holes 1T1 to 3T1 may be separately formed. For example, the fourth and fifth via holes 4T1 and 5T1 may be formed simultaneously or separately. For example, the fourth and fifth via holes 4T1 and 5T1 are also formed in a process of forming the first to third via holes 1T1 to 3T1. That is, while the first to third via holes 1T1 to 3T1 are completely formed, the fourth and fifth via holes 4T1 and 5T1 are first formed to a first depth corresponding to a part of a total depth, and afterwards, a remaining depth of the fourth and fifth via holes 4T1 and 5T1 may be formed by performing only a process of forming the fourth and fifth via holes 4T1 and 5T1.

FIG. 15 is a plan view of FIG. 14 cut along the 15-15′ line in FIG. 14. The reflective layer 120 on the dummy micro-LED MD1′ is exposed through the fourth via hole 4T1, and the first electrode layer 116 on the active micro-LED MD1 is exposed through the fifth via hole 5T1. When the reflective layer 120 extends over the entire plurality of micro-LEDs MD1, only one dummy micro-LED MD1′ may be provided, but embodiments are not limited thereto.

After forming the first to fifth via holes 1T1 to 5T1, as shown in FIG. 16, a first metal layer 150 may be formed in the first via hole 1T1, a second metal layer 144 may be formed in the second via hole 2T1, a third metal layer 146 may be formed in the third via hole 3T1, a fourth metal layer 152 may be formed in the fourth via hole 4T1, and a fifth metal layer 148 may be formed in the fifth via hole 5T1, respectively. The first to fifth metal layers 150, 144, 146, 152, and 148 may be simultaneously formed, but may not be simultaneously formed in consideration of the depth of each of the via holes 1T1 to 5T1. For example, when the depths of the via holes are the same or the difference is not large, the metal layers may be formed at the same time, and if the depths of the via holes are relatively deep, the metal layers may be formed in separate processes. For example, the first metal layer 150 may be formed in the shape as illustrated in FIG. 3, and the second to fifth metal layers 144, 146, 152, and 148 may be formed in a similar shape.

For example, in order to drive the micro-LED MD1 and block a bottom gate effect, the first to third metal layers 150, 144, and 146 and the fourth metal layer 152 are formed to be apart from each other, and the third metal layer 146 and the fifth metal layer 148 are formed to be connected to each other. In this way, the first display 100 may be formed.

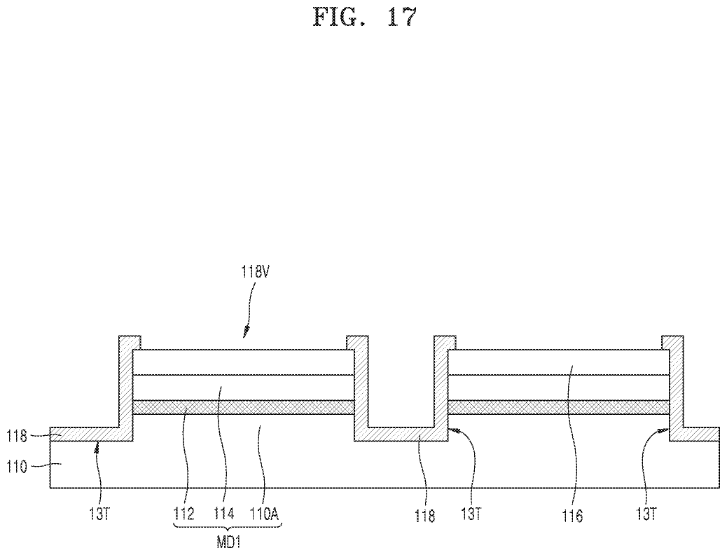

FIGS. 17, 18, 19, 20, and 21 are cross-sectional views illustrating a method of manufacturing an ultra-high ppi micro-LED display according to an example embodiment. A method of manufacturing a micro-LED according to an example embodiment (hereinafter, a second manufacturing method) is described with reference to FIGS. 17 to 21. The second manufacturing method may be an example manufacturing method for the second display 200 described above.

Referring to FIG. 17, the first manufacturing method is followed until the operation of forming the plurality of micro-LEDs MD1 on the substrate 110. After forming the micro-LED MD1, a current blocking layer 118 is formed on sides and bottom of the trench 13T. Accordingly, side surfaces of the micro-LED MD1 and side surfaces of the first electrode layer 116 are covered with the current blocking layer 118. The current blocking layer 118 may extend over a partial region of the first electrode layer 116, but is limited to near both ends of the first electrode layer 116. A via hole 118V exposing an upper surface of the first electrode layer 116 is formed in the current blocking layer 118. Most of the upper surface of the first electrode layer 116 may be exposed through the via hole 118V.

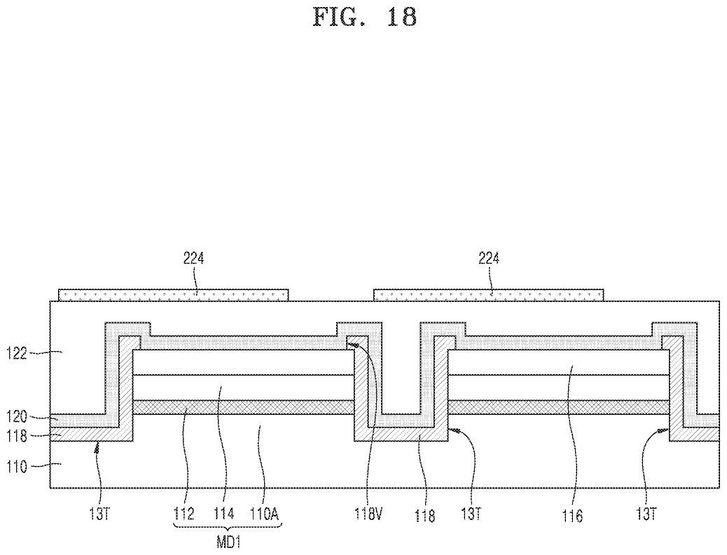

Referring to FIG. 18, a reflective layer 120 is formed on the current blocking layer 118 and the first electrode layer 116. The reflective layer 120 may be formed along a surface of the current blocking layer 118, and is formed to cover the entire upper surface of the first electrode layer 116 exposed through the via hole 118V. The reflective layer 120 may directly contact the entire exposed upper surface of the first electrode layer 116. A step is formed between the current blocking layer 118 and the first electrode layer 116 on the micro-LED (MD1), and the step also appears on the reflective layer 120 on the micro-LED (MD1) due to the step. In an example, the reflective layer 120 may be formed flat without a step on the micro-LED MD1 through a thickness control and planarization process of the reflective layer 120.

Next, a first interlayer insulating layer 122 is formed on the reflective layer 120, and a planarization process is applied to the first interlayer insulating layer 122 to flatten an upper surface of the first interlayer insulating layer 122. The first interlayer insulating layer 122 may be formed to completely fill the trench 13T and cover the entire surface of the reflective layer 120. A plurality of sixth metal layers 224 apart from each other are formed on the first interlayer insulating layer 122. The plurality of sixth metal layers 224 may be formed to correspond one-to-one to the micro-LED MD1. Also, the sixth metal layer 224 and the micro-LED MD1 may be formed to have an arrangement relationship described in the second display 200.

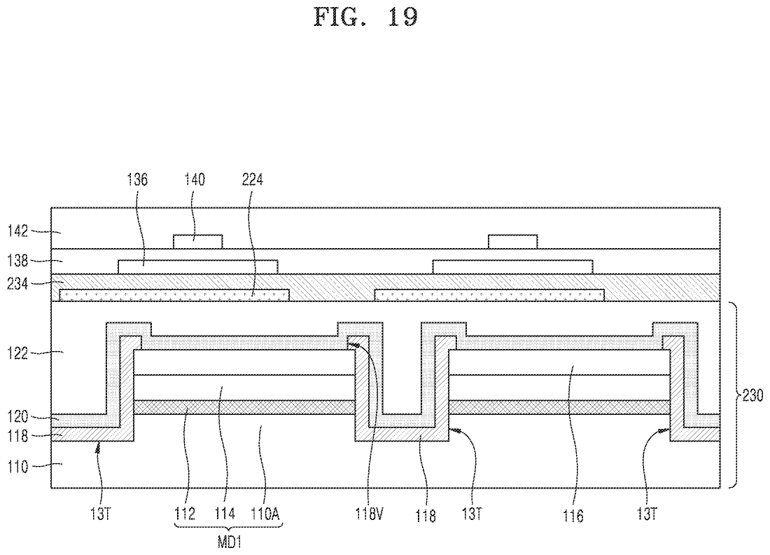

Referring to FIG. 19, a buffer layer 234 covering the plurality of sixth metal layers 224 is formed on the first interlayer insulating layer 122. An upper surface of the buffer layer 234 is formed to be flat by using a planarization process. A plurality of channel layers 136, a second interlayer insulating layer 138, a gate electrode layer 140, and a third interlayer insulating layer 142 are sequentially formed on the buffer layer 234. This process may follow the first manufacturing method. In this case, the entire channel layer 136 may be formed to be located on the sixth metal layer 224.

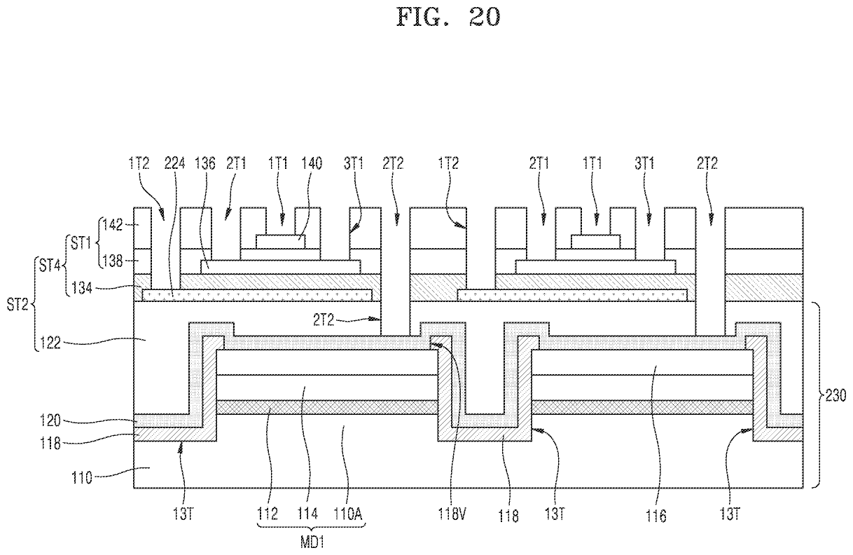

Referring to FIG. 20, as described in the first manufacturing method, first to third via holes 1T1 to 3T1 are formed, a sixth via hole 1T2 through which one side of the sixth metal layer 224 is exposed is formed in the fourth stack ST4 including the buffer layer 134, the second interlayer insulating layer 138, and the third interlayer insulating layer 142, and a seventh via hole 2T2 through which the reflective layer 120 on the micro-LED MD1 is exposed is formed in the second stack ST2 including the first interlayer insulating layer 122, the buffer layer 134, the second interlayer insulating layer 138, and the third interlayer insulating layer 142. The process of forming the via holes 1T1 to 3T1, 1T2 and 2T2 may follow the process of forming the via holes 1T1 to 5T1 described with reference to FIG. 14.

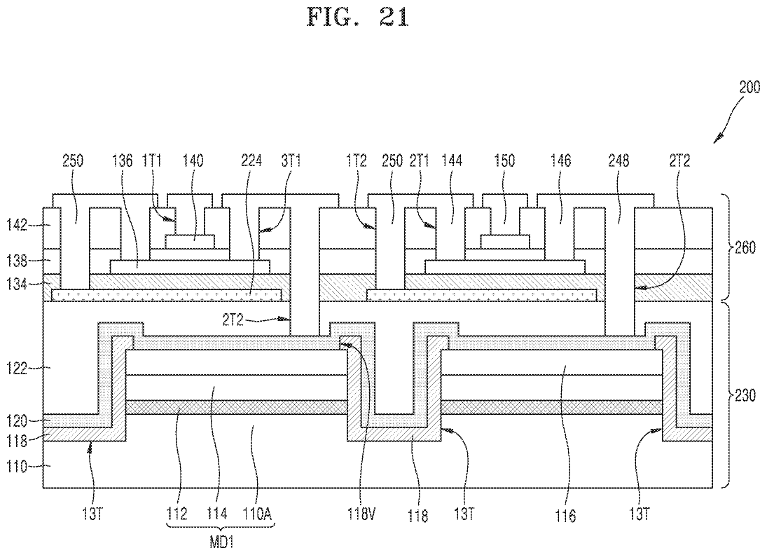

Referring to FIG. 21, a first metal layer 150 is formed in the first via hole 1T1, a second metal layer 144 is formed in the second via hole 2T1, a third metal layer 146 is formed in the third via hole 3T1, a seventh metal layer 250 is formed in the sixth via hole 1T2, and an eighth metal layer 248 is formed in the seventh via hole 2T2. For example, the first to third metal layers 150, 144, and 146, the seventh metal layer 250, and the eighth metal layer 248 may be simultaneously formed, but may not be simultaneously formed. For example, the first to third metal layers 150, 144, and 146 and the seventh metal layer 250 that fill via holes having the same or similar depth may be simultaneously formed, and the eighth metal layer 248 may be separately formed. For example, the first to third metal layers 150, 144, and 146 may be formed to be apart from each other. For example, the second and seventh metal layers 144 and 250 may be simultaneously formed to be connected to each other. For example, the third metal layer 146 and the eighth metal layer 248 may be simultaneously formed to be connected to each other. The first to third metal layers 150, 144, and 146 and the seventh and eighth metal layers 250 and 248 may be formed by covering inclined side surfaces and a bottom surface of the via hole 1T1 like the first metal layer 150 of FIG. 3, instead of filling the via holes.

In the second manufacturing method described above, the sixth metal layer 224 may be formed to cover an entire upper surface of the first interlayer insulating layer 122 like the ninth metal layer 315 shown in FIGS. 6 and 7, and may be formed to be apart from the seventh via hole 2T2, or, without forming the sixth via hole 1T2 and the seventh metal layer 250, a separate metal layer (a metal layer corresponding to the 10th metal layer 325 in FIG. 6) connected to the sixth metal layer 224 may be formed.

The disclosed ultra-high ppi micro-LED display includes a field shielding member between the micro-LED and a switching device in a structure in which the micro-LED and the switching device are sequentially formed to form a single body. A bias voltage for field shielding is applied to the field shielding member during an operation of the micro-LED, and accordingly, it is possible to block a field generated from the micro-LED from being applied to a channel of the switching device during an operation of the micro-LED. Therefore, if the disclosed ultra-high ppi micro-LED display is used, it is possible to prevent malfunction of a switching device due to a bottom gate effect that appears in an operation of the ultra-high ppi micro-LED display of the related art, thereby increasing the operation reliability of the ultra-high ppi micro-LED display.

It should be understood that example embodiments described herein should be considered in a descriptive sense only and not for purposes of limitation. Descriptions of features or aspects within each example embodiment should typically be considered as available for other similar features or aspects in other embodiments. While example embodiments have been described with reference to the figures, it will be understood by those of ordinary skill in the art that various changes in form and details may be made therein without departing from the spirit and scope as defined by the following claims and their equivalents.

What is claimed is:

1. An ultra-high pixel per inch (ppi) micro-light-emitting diode (LED) display comprising:
a micro-LED layer comprising a plurality of micro-LEDs; and
a backplane layer comprising a switching device connected to the micro-LED layer, and
a field shielding member provided between the plurality of micro-LEDs and the switching device, the field shielding member configured to shield the switching device from a field applied to the switching device from the plurality of micro-LEDs during an operation of the micro-LED display,
wherein the micro-LED layer and the backplane layer form a single body in a sequentially stacked structure.

2. The micro-LED display of claim 1, wherein the field shielding member comprises
a reflective layer configured to reflect light emitted from the plurality of micro-LEDs; and
a metal layer provided as a contact terminal and configured to apply a voltage to the reflective layer.

3. The micro-LED display of claim 2, wherein the plurality of micro-LEDs comprises:
at least one active micro-LED; and
an inactive dummy micro-LED.

4. The micro-LED display of claim 3, wherein the reflective layer is provided on a surface of the at least one active micro-LED facing the switching device,
wherein the reflective layer does not electrically contact the at least one active micro-LED, and
wherein the metal layer is provided on the inactive dummy micro-LED.

5. The micro-LED display of claim 4, further comprising a current blocking layer provided on at least a side surface of the at least one active micro-LED and between the reflective layer and the at least one active micro-LED.

6. The micro-LED display of claim 1, wherein the switching device comprises a channel layer,
wherein the field shielding member is connected to a first side of the channel layer, and
wherein the micro-LED layer is connected to a second side of the channel layer that is different from the first side of the channel layer.

7. The micro-LED display of claim 6, wherein the entire channel layer is provided on the field shielding member.

8. The micro-LED display of claim 7, wherein the field shielding member comprises a metal layer.

9. The micro-LED display of claim 8, further comprising a reflective layer contacting the plurality of micro-LEDs,
wherein the reflective layer is between the plurality of micro-LEDs and the switching device, and
wherein the reflective layer is connected to the channel layer through the metal layer.

10. The micro-LED display of claim 1, wherein the switching device comprises a plurality of switching devices, and
wherein the field shielding member comprises:
a single metal layer corresponding to the plurality of switching devices and separated from the plurality of micro-LEDs; and
a metal layer provided as a contact terminal and configured to apply a voltage to the single metal layer.

11. The micro-LED display of claim 10, wherein the switching device comprises a channel layer, and
wherein the micro-LED is connected to one side of the channel layer.

12. The micro-LED display of claim 11, wherein a reflective layer is provided between the switching device and the plurality of micro-LEDs, and
wherein the plurality of micro-LEDs is connected to the channel layer through the reflective layer.

13. A method of manufacturing an ultra-high pixel per inch (ppi)micro-light-emitting diode (LED) display, the method comprising:
forming a plurality of micro-LEDs on a substrate;
forming a reflective layer on the plurality of micro-LEDs;
forming an interlayer insulating layer on the reflective layer;
forming a switching device on the interlayer insulating layer; and
connecting the switching device to the plurality of micro-LEDs,
wherein the plurality of micro-LEDs comprises:
a plurality of active micro-LEDs, and
an inactive micro-LED,
wherein the switching device is connected to the plurality of active micro-LEDs,
wherein the reflective layer does not directly contact the plurality of micro-LEDs, and
wherein a metal layer as a voltage applying terminal is formed on the reflective layer and on the inactive micro-LED.

14. The method of claim 13, further comprising forming a current blocking layer between the reflective layer and the plurality of micro-LEDs.

15. A method of manufacturing an ultra-high pixel per inch (ppi)micro-light-emitting diode (LED) display, the method comprising:
forming a micro-LED on a substrate;
forming a reflective layer on the micro-LED, the reflective layer contacting the micro-LED;
forming an interlayer insulating layer on the reflective layer;
forming a field shielding member on the interlayer insulating layer;
forming a buffer layer on the field shielding member, the field shielding member being provided on the interlayer insulating layer;
forming a switching device on the buffer layer; and
connecting a first side of the switching device to the field shielding member and a second side of the switching device to the micro-LED.

16. The method of claim 15, wherein the switching device comprises a channel layer connected to the field shielding member and the micro-LED,
wherein the field shielding member comprises a metal layer, and
wherein the entire channel layer is on the metal layer.

17. A method of manufacturing an ultra-high pixel per inch (ppi)micro-light-emitting diode (LED) display, the method comprising:
forming a micro-LED on a substrate;
forming a reflective layer on the micro-LED, the reflective layer contacting the micro-LED;
forming an interlayer insulating layer on the reflective layer;
forming a field shielding member on the interlayer insulating layer;
forming a buffer layer on the field shielding member, the field shielding member being provided on the interlayer insulating layer;
forming a switching device on the buffer layer; and
connecting the switching device to the micro-LED,
wherein the field shielding member comprises:
a metal layer that does not directly contact the switching device and the micro-LED; and
a voltage applying terminal connected to the metal layer.

18. A method of operating an ultra-high pixel per inch (ppi)micro-light-emitting diode (LED) display comprising a micro-LED and a switching device connected to the micro-LED, the method comprising:
shielding the switching device from a field applied to the switching device from the micro-LED during an operation of the micro-LED display by applying, to a field shielding member, a bias voltage,
wherein the field shielding member is between the micro-LED and the switching device, and
wherein the field shielding member is electrically insulated from the micro-LED.

19. The method of claim 18, wherein the switching device comprises a channel layer,
wherein the field shielding member is connected to one side of the channel layer, and
wherein the bias voltage is supplied to the field shielding member through the switching device.

20. The method of claim 18, wherein the bias voltage is directly applied to the field shielding member without passing through the switching device.
